(19) United States
(12) Patent Application Publication
(10) Pub. No.: US 2014/0166074 A1
(43) Pub. Date: Jun. 19, 2014

(54) METHODS AND SYSTEMS FOR INCREASING THE YIELD OF PHOTOVOLTAIC MODULES

(71) Applicants: Marath Prakash, Bangalore (IN); Sandeep Rammohan Koppikar, Bangalore (IN); Rajesh Manapat, Bangalore (IN); Nagendra Srinivas Cherukapalli, Cupertino, CA (US); Narayan Saligram, Bangalore (IN)

(72) Inventors: Marath Prakash, Bangalore (IN); Sandeep Rammohan Koppikar, Bangalore (IN); Rajesh Manapat, Bangalore (IN); Nagendra Srinivas Cherukapalli, Cupertino, CA (US); Narayan Saligram, Bangalore (IN)

(21) Appl. No.: 14/106,430

(22) Filed: Dec. 13, 2013

Related U.S. Application Data
(60) Provisional application No. 61/737,577, filed on Dec. 14, 2012.

(51) Int. Cl. H01L 31/052

(52) U.S. Cl. CPC H01L 31/052
USPC 136/246

(57) ABSTRACT

Photovoltaic (PV) assemblies are described. Example PV assemblies include a mounting structure, a PV module coupled to the mounting structure, and a cooling mechanism.

### CROSS-REFERENCE TO RELATED APPLICATIONS

This application claims priority to U.S. Provisional Application No. 61/737,577 filed Dec. 14, 2012, the entire disclosure of which is hereby incorporated by reference in its entirety.

### FIELD

This disclosure generally relates to photovoltaic modules and, more specifically, to methods and systems for increasing the yield of photovoltaic modules.

### BACKGROUND

Photovoltaic (PV) modules are devices which convert solar energy into electricity. Some known PV modules convert around 85% of incoming sunlight into heat. During peak conditions, this can result in a heat-generation of 850 W/m² and PV module temperatures as high as 70° C. The electrical power produced by PV modules decreases linearly with increase in module temperature. Accordingly, a more efficient PV module is needed.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

According to one aspect of the present disclosure, a photovoltaic (PV) assembly includes a PV module including a solar panel comprising a top surface and a bottom surface. A first rail and a second rail are coupled to the PV module. The first rail and the second rail are configured to support the PV module and extend below the bottom surface of the PV module. A cooling fin assembly is removably coupled against the bottom surface of the PV module. The cooling fin assembly includes a base coupled to the bottom surface of the PV module, a plurality of thermally conductive cooling fins attached to the base, and a biasing assembly extending from at least one of the first rail and the second rail to the base. The cooling fins extend from the base away from the bottom surface of the PV module, and the biasing assembly is configured to bias the base against the bottom surface of the PV module.

Another aspect is a PV assembly including a mounting structure, a PV module coupled to the mounting structure, and a plurality of thermally conductive bristles coupled between the PV module and the mounting structure. The PV module includes a solar panel.

According to still another aspect, a PV assembly includes a PV module including a solar panel with a top surface and a bottom surface. A first rail and a second rail are coupled to the PV module. The first rail and the second rail are configured to support the PV module and extend below the bottom surface of the PV module. A cooling fluid assembly is coupled against the bottom surface of the PV module. The cooling fluid assembly includes a conduit assembly coupled to the bottom surface of the PV module. The conduit assembly includes at least one conduit configured for containing a flow of heat transfer fluid through the at least one conduit, and a connector assembly extending from at least one of the first rail and the second rail to the conduit assembly. The connector assembly is configured to maintain the conduit assembly against the bottom surface of the PV module.

One aspect is a PV assembly including a PV module with a solar panel having a top surface and a bottom surface. A header is coupled to a first end of the PV module. The header module includes at least one port configured to dispense a heat transfer fluid onto the top surface of said PV module. A collector assembly is coupled to a second end of the PV module opposite the first end of the PV module. The collector assembly is configured to collect heat transfer fluid from the top surface of the PV module. The first end of the PV module is at a higher elevation than the second end of the PV module.

Another aspect is a PV assembly including a PV module with a solar panel having a top surface and a bottom surface. A first rail and a second rail are coupled to the PV module and configured to support the PV module and extend below the bottom surface of the PV module. An air cooling assembly is coupled adjacent the bottom surface of the PV module. The air cooling assembly includes a nozzle assembly with at least one nozzle. The nozzle assembly is configured to receive a flow of air and direct a flow of air across the bottom surface of the PV module. A connector assembly extends from at least one of the first rail and the second rail to the nozzle assembly. The connector assembly is configured to position the nozzle assembly adjacent the bottom surface of the PV module.

According to another aspect of the disclosure, a PV assembly includes a PV module with a plurality of laminated layers. The PV module has a top surface, a bottom surface, and a plurality of edges generally extending between the top surface and the bottom surface. The plurality of layers include a solar cell having a top side and a bottom side, a first encapsulant layer adjacent the top side of the solar cell, a second encapsulant layer below the bottom side of the solar cell, and a thermally conductive sheet below the bottom side of the solar cell. The thermally conductive sheet extends beyond one of the plurality of edges of the PV module.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of a PV module of one embodiment;

FIG. 2 is a cross-sectional view of the PV module shown in FIG. 1 taken along the line A-A;

FIG. 3 is a simplified cross-sectional view of a PV module assembly including the PV module shown in FIG. 1 with a cooling fin assembly;

FIG. 4 is a cross section of a fin of the cooling fin assembly shown in FIG. 3;

FIG. 5 is a simplified diagram of an installation of the PV assembly shown in FIG. 3;

FIG. 6 is a cross-sectional view of a PV assembly including a bristle cooling system coupled to the PV module shown in FIG. 1;

FIG. 7 is a PV assembly including a pipe cooling system is coupled to the PV module shown in FIG. 1;

FIG. 8 is a PV assembly including another pipe cooling system coupled to the PV module shown in FIG. 1;

FIG. 9 is a PV assembly including yet another pipe cooling system coupled to the PV module shown in FIG. 1;

FIG. 10 is a cross-sectional view of a PV assembly including the PV module shown in FIG. 1 with an air duct cooling system;

FIG. 11 is a top plan view of a PV assembly including the PV module shown in FIG. 1 with a top surface cooling system;

FIG. 12 is a side view of the PV assembly shown in FIG. 11;

FIG. 13 is a cross-sectional view of a PV system including the PV module shown in FIG. 1 with a forced air cooling system coupled to its bottom surface;

FIG. 14 is a cross-sectional view of a PV system including the PV module shown in FIG. 1 with another forced air cooling system coupled to its bottom surface;

FIG. 15 is a cross-sectional view of a PV assembly including the PV module shown in FIG. 1 with a cooling system including a thermally conductive sheet integrated into module the PV module;

FIG. 16 is a cross-sectional view of another PV assembly including the PV module shown in FIG. 1 with a cooling system including a thermally conductive sheet integrated into module the PV module; and

FIG. 17 is a PV assembly including two of the assemblies shown in FIGS. 15 and 16.

Like reference symbols in the various drawings indicate like elements.

### DETAILED DESCRIPTION

The embodiments described herein generally relate to photovoltaic (PV) modules. More specifically, embodiments described herein relate to methods and systems for increasing the yield of PV modules by reducing the temperature of the PV modules.

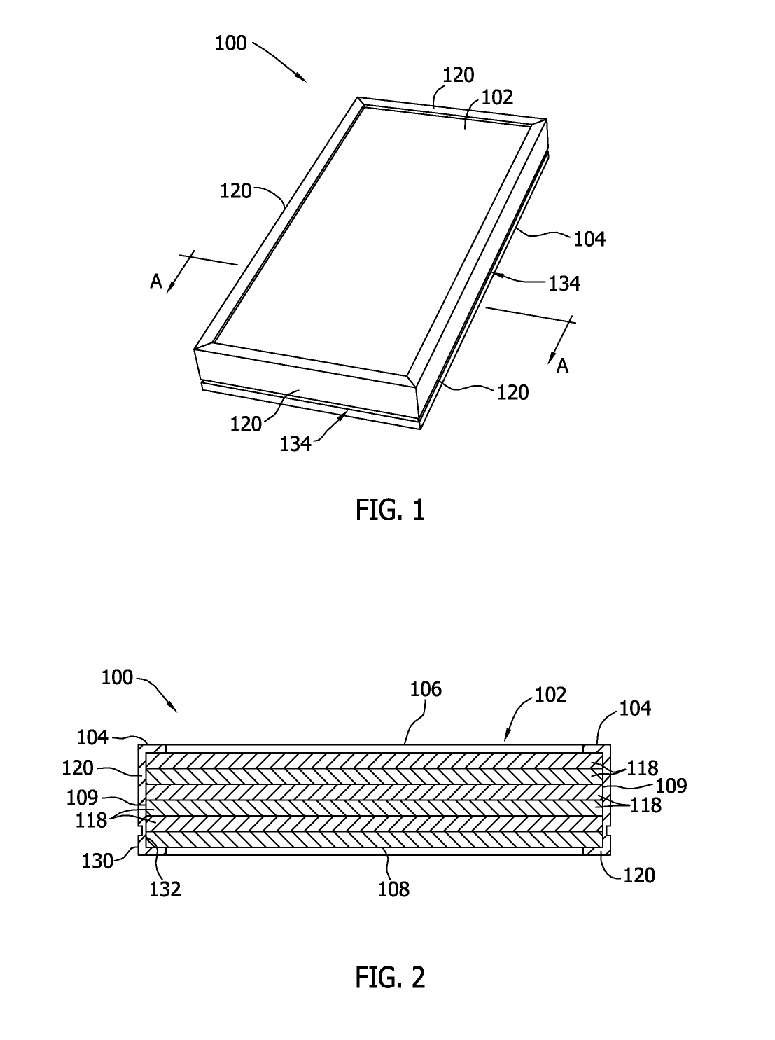

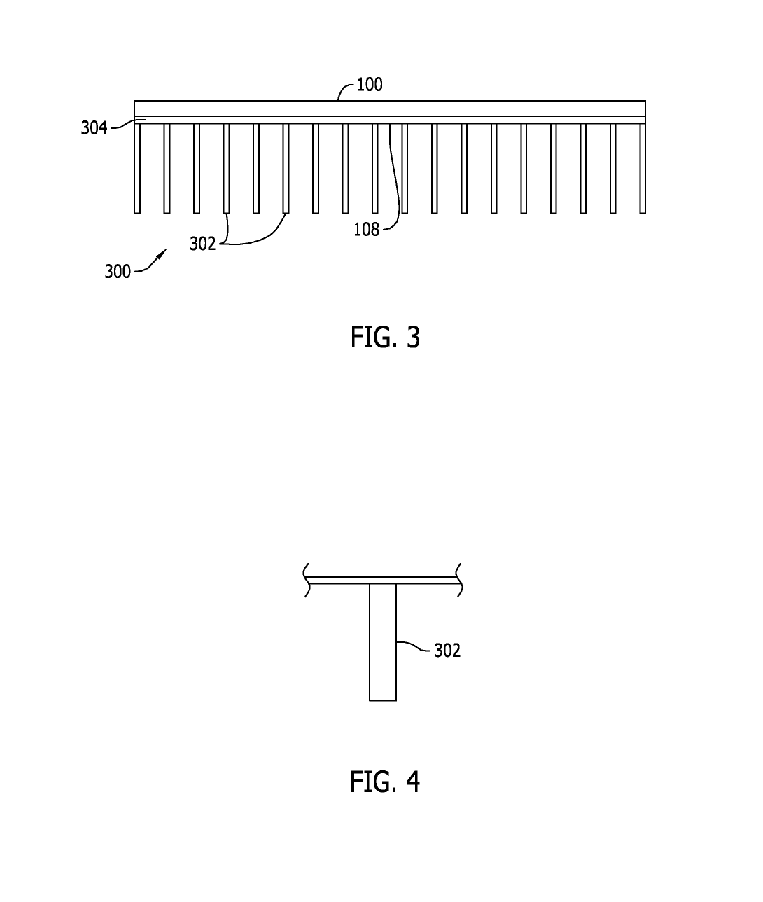

Referring initially to FIGS. 1 and 2, a PV module of one embodiment is indicated generally at 100. A perspective view of PV module 100 is shown in FIG. 1. FIG. 2 is a cross sectional view of PV module 100 taken at line A-A shown in FIG. 1. PV module 100 includes a solar panel 102 and a frame 104 circumscribing solar panel 102.

Solar panel 102 includes a top surface 106 and a bottom surface 108 (shown in FIG. 2). Edges 109 extend between top surface 106 and bottom surface 108. In this embodiment, solar panel 102 is rectangular shaped. In other embodiments, solar panel 102 may have any suitable shape including, for example, square, pentagonal, hexagonal, etc.

As shown in FIG. 2, this solar panel 102 has a laminate structure that includes several layers 118. Layers 118 may include for example glass layers, non-reflective layers, electrical connection layers, n-type silicon layers, p-type silicon layers, and/or backing layers. In other embodiments, solar panel 102 may have more or fewer, including one, layers 118, may have different layers, and/or may have different types of layers.

As shown in FIG. 1, frame 104 circumscribes solar panel 102. Frame 104 is coupled to solar panel 102, as best seen in FIG. 2. Frame 104 assists in protecting edges 109 of solar panel 102. In this embodiment, frame 104 is constructed of four frame members 120. In other embodiments frame 104 may include more or fewer frame members 120.

Exemplary frame 104 includes an outer surface 130 spaced apart from solar panel 102 and an inner surface 132 adjacent solar panel 102. Outer surface 130 is spaced apart from and substantially parallel to inner surface 132. Frame 104 is suitably made of aluminum, and particularly, is made of 6000 series anodized aluminum. In other embodiments, frame 104 may be made of any other suitable material providing sufficient rigidity including, for example, rolled or stamped stainless steel, plastic, or carbon fiber.

FIGS. 3-17 illustrate various embodiments of cooling systems for use with, or incorporated into, PV modules, such as PV Module 100. In each, the cooling system is in thermal communication to transfer heat from the PV module.

FIGS. 3-5 illustrate an exemplary embodiment of PV assemblies in which foil fins are used as a cooling system to cool PV module 100. The foil fins are in thermal communication with the PV module, as further described below.

FIG. 3 is a simplified cross-sectional view of a PV assembly including PV module 100 having a cooling fin assembly 300 attached. Fin assembly 300 includes a plurality of fins 302. FIG. 4 is a cross section of one fin 302. Fin assembly 300 is in contact with bottom surface 108 of PV module 100. More particularly, fin assembly 300 contacts a backsheet 304 of PV module 100 to transport heat away from PV module 100 via convection and/or radiation. In this embodiment, fin assembly 300 is in direct contact with bottom surface 108 of PV module 100. In other embodiments, fin assembly 300 may be indirectly coupled to bottom surface 108, such as via a thermally conductive intermediary. For example, a thermally conductive paste, a thermally conductive putty, a thermally conductive adhesive, etc. may be positioned between fin assembly 300 and PV module 100.

In this embodiment, fins 302 are foil fins. The fins 302 are made from metal foil. In other embodiments, fins 302 may be constructed of any other suitable heat conductive material including, for example, other metal foils, thermally conductive plastics, etc. Suitable metal foils include any metal foil with relatively high thermal conductivity, relatively low density, relatively high malleability to allow forming into different shapes, and relatively high corrosion resistance. In one preferred embodiment, fins 302 are made from aluminum foil. In other embodiments, fins 302 are made of copper foil. In some embodiments, fins 302 are constructed from metal foil having a thickness less than about 1 millimeter. In this embodiment fin assembly 300 is of unitary, one-piece construction of a single material, but in other embodiments, assembly 300 may include more than one material. For example, fins 300 may be constructed of a first material, and coupled to a base made of a second material that is a different type of material. Fins 302 may also be coated to enhance emissivity in the infrared spectrum. For example, fins 302 may be coated with black paint to enhance the emissivity of fins 302. In other embodiments, fins 302 may be made of black anodized aluminum to enhance emissivity over non-anodized aluminum.

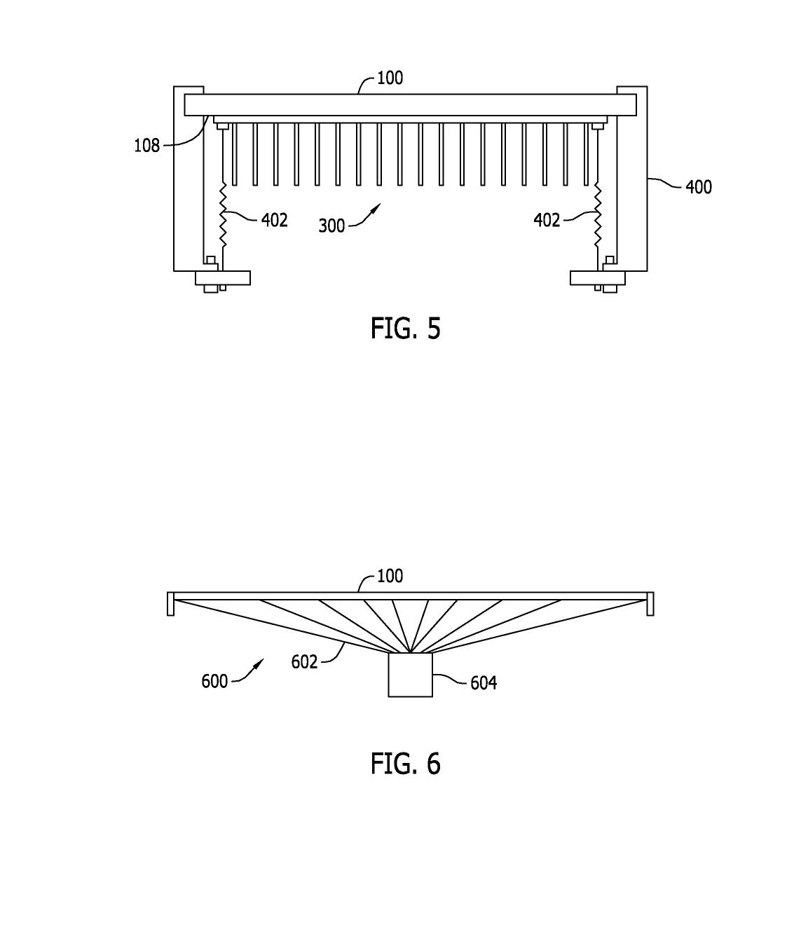

FIG. 5 is a simplified diagram of an installation of the PV assembly including PV module 100 with cooling fin assembly 300 removably coupled to the module. PV module 100 is mounted on support rails 400. A biasing assembly includes springs 402 that extend from rails 400 to fin assembly 300. Springs 402 bias fin assembly 300 against bottom surface 108 of PV module 100. In other embodiments fin assembly 300 may be coupled to PV module by other suitable methods or structures. For example, fin assembly is coupled to back surface 108 of PV module 100 using a thermally conductive adhesive.

FIG. 6 is a simplified cross-sectional view of a PV assembly including a bristle cooling system 600 coupled to PV module 100. Bristle cooling system includes a plurality of thermally conductive bristles 602 in contact with back surface 108 of PV module 100. Bristles 602 are elastic bristles having a relatively high thermal conductivity. Sheets or foils of thermally conductive materials, such as aluminium, copper, etc., can be used to make bristles 602. The cross-section of bristles 602 may be of any suitable shape that is small when compared to its length. Bristles 602 are coupled to a support structure 604 and are sized to extend from support structure 604 to contact back surface 108 of PV module 100. In this embodiment, support structure 604 is a metallic torque tube of a solar tracker system to which PV module 100 is mounted. In other embodiments, support structure 602 may be any thermally conductive component to which bristles 602 may be coupled so as to extend to contact PV module 100. Support structure 604 is located underneath PV module 100, is generally shaded from the sun by PV module 100, and thus is generally cooler than PV module 100. Accordingly, bristles 300 conduct heat from PV module 100 to support structure 604, which acts as a heat sink for PV module 100. Support structure may also include a cooling mechanism such as cooling fins. In some embodiments, bristles 602 are rigidly attached to back surface 108 of PV module 100 and support structure 604. In other embodiments, bristles 602 are rigidly attached to support structure 604 and contact back surface 108 of PV module 100 without being rigidly attached thereto.

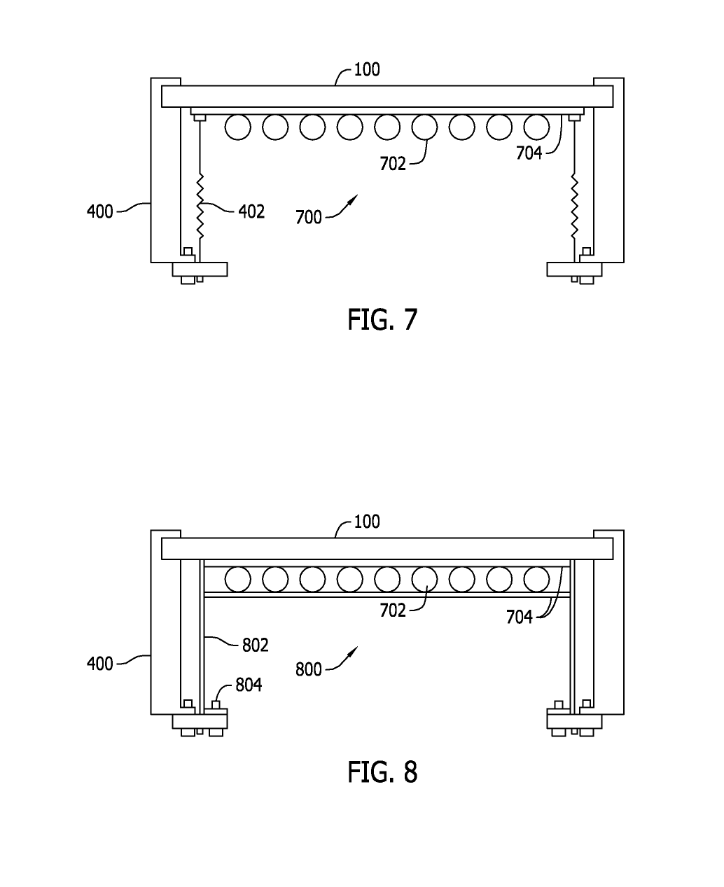

FIGS. 7-9 are simplified diagrams of PV assemblies including PV module 100 with pipe cooling systems in thermal communication with PV module 100.

In FIG. 7, a pipe cooling system 700 is coupled to PV module 100 using springs 402. Pipe cooling system 700 includes thermally conductive pipes 702 coupled to a thermally conductive sheet 704.

In FIG. 8, a pipe cooling system 800 for PV module 100 is bolted to rails 400. Pipe cooling system 800 includes thermally conductive pipes 702 coupled between two thermally conductive sheets 704. Legs 802 support pipe cooling assembly 802 and are coupled to rails 400 using fasteners 804. In this embodiment fasteners 804 are bolts. In other embodiments, fasteners 804 may be any other suitable type of fastener including, for example, screws, rivets, etc.

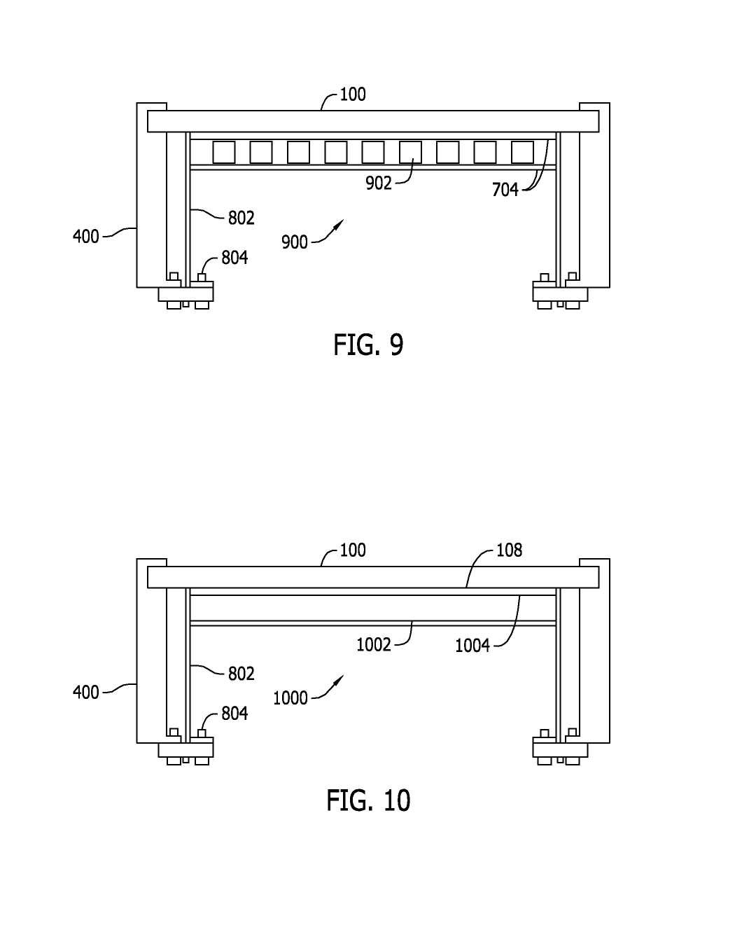

Similarly in FIG. 9, a pipe cooling system 900 for PV module 100 is bolted to rails 400. Pipe cooling system 900 includes thermally conductive pipes 902 coupled between two thermally conductive sheets 704. Legs 802 support pipe cooling assembly 802 and are coupled to rails 400 using fasteners 804. In this embodiment fasteners 804 are bolts. In other embodiments, fasteners 804 may be any other suitable type of fastener including, for example, screws, rivets, etc.

Pipe cooling systems 700, 800, 900 all include thermally conductive pipes. Pipes 702 have a circular cross-section, while pipes 902 have a square cross-section. In other embodiments, pipes 702, 902 may have any other suitable cross sectional shape. In these embodiments, pipes 702, 902 are metallic pipes. In other embodiments, pipes 702, 902 may be any other suitable thermally conductive material. In these embodiments, pipes 702, 902 are arranged spaced apart and parallel to each other along PV module 100. In other embodiments, pipes 702, 902 may be arranged in any orientation, spacing, geometry, etc. that provides a desired heat transfer.

Pipes 702, 902 are attached to conductive sheet(s) 704 by using thermal adhesives, welding, brazing or any other techniques that will ensure a good thermal contact between pipes 702, 902 and sheet(s) 704. Thermal compounds may be applied between the conductive sheet 704 and the PV module 100 to enhance thermal contact between conductive sheet 704 and PV module 100.

A heat transfer fluid (not shown) flows through pipes 702, 902. In this embodiment, the heat transfer fluid is water. In other embodiments, the heat transfer fluid may be any fluid suitable for heat transfer as described herein including, for example, ethylene glycol, air, and/or heat transfer oil. Heat is transferred from PV module 100 to conductive sheet 704 and pipes 702, 902. The heat transfer fluid is heated by pipes 702, 902 as it flows through pipes 702, 902. The heat transfer fluid flows to a location away from PV module where it can be cooled to release the heat it received from PV module 100 and recirculated. Moreover, in some embodiments, the heat carried by the transfer fluid may be used for another application. For example, the heat carried by the transfer fluid may be used to heat water, to increase the temperature in a building, etc.

FIG. 10 is a cross-sectional view of an installation of PV module 100 with an air duct cooling system 1000. System 1000 includes a duct 1002 supported by legs 802. Heat transfer fluid (not shown) is carried through duct 1002 to remove heat from PV module 100 in a manner similar to pipe cooling systems 700, 800, 900. In this embodiment, duct 1002 has a rectangular geometry. In other embodiments, duct 1002 may have any other suitable shape. A top surface 1004 of duct 1002 is in thermal contact with bottom surface 108 of PV module 100. Top duct surface 1004 is constructed of any material having good thermal conductivity. The other surfaces of duct 1002 may be made of any light weight, low cost material. In some embodiments, duct 1002 does not include top surface 1004. Instead, bottom surface 108 of PV module functions as top surface 1004 and the heat transfer fluid in duct 1002 is in direct contact with the bottom surface 108.

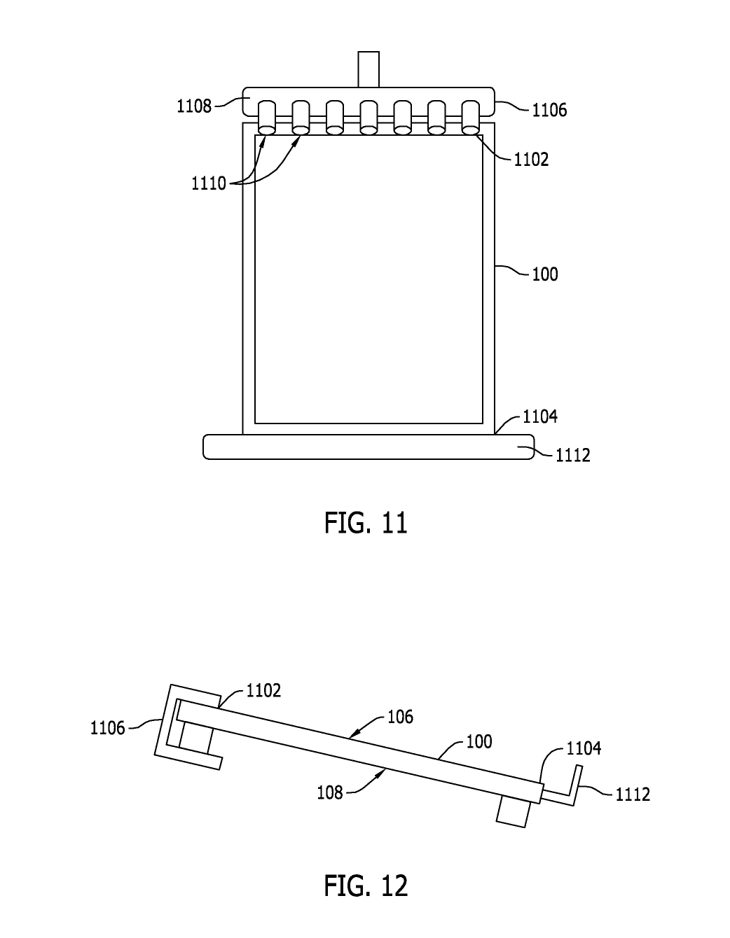

FIGS. 11-12 show a PV assembly with a top surface cooling system 1100 coupled to PV module 100. FIG. 11 is a top plan view of PV module 100 with system 1100 attached, while FIG. 12 is a side view of PV module 100 and system 1100. Cooling system 1100 dispenses a heat transfer fluid onto top surface 106 of PV module 100 at a dispensing location 1102 of PV module 100 that is at a higher elevation than a collection location 1104 when PV module 100 is installed. A pipe assembly 1106 includes a header 1108 with multiple openings 1110. Heat transfer fluid is pumped into header 1108 and dispensed through openings 1110 onto top surface 106. The heat transfer fluid is any suitable heat transfer fluid that will allow the solar radiation to pass through it. In this embodiment, the heat transfer fluid is water. In other embodiments, other heat transfer fluids may be used. Gravity causes the heat transfer fluid flows down the top surface 108 toward collection point 1104. Along the way, the heat transfer fluid picks up the heat from top surface 108. The fluid is then collected in a collection unit 1112 at the collection point 1104. The heat transfer fluid is then cooled and re-circulated by system 1100. The flow rate of the fluid may be adjusted, such as by varying the number, size, and/or geometry of openings 1110, to provide a relatively low evaporative loss of the heat transfer fluid as it traverses the top surface 106 from between locations 1102 and 1104.

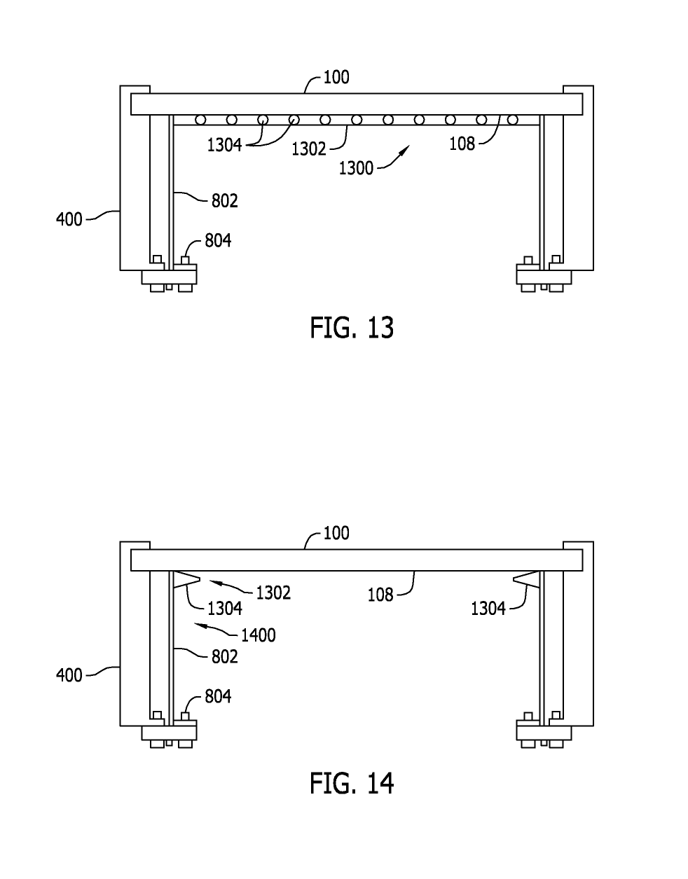

FIGS. 13 and 14 are cross sectional views of a PV assembly including PV module 100 with forced air cooling systems attached. More specifically, in FIG. 13 PV module has a forced air cooling system 1300 coupled to bottom surface 108, and FIG. 14 has a forced air cooling system 1400 coupled to bottom surface 108. Cooling systems 1300, 1400 both use one or more arrays 1302 of air nozzles 1304. Air is forced through the nozzle arrays 1302 at the bottom surface 108 of the module 100. The air impinging on bottom surface 108 cools the PV module 100. The air used may be at ambient temperature or it may be cooled before it is passed onto the nozzles 1304 based on the desired amount of cooling.

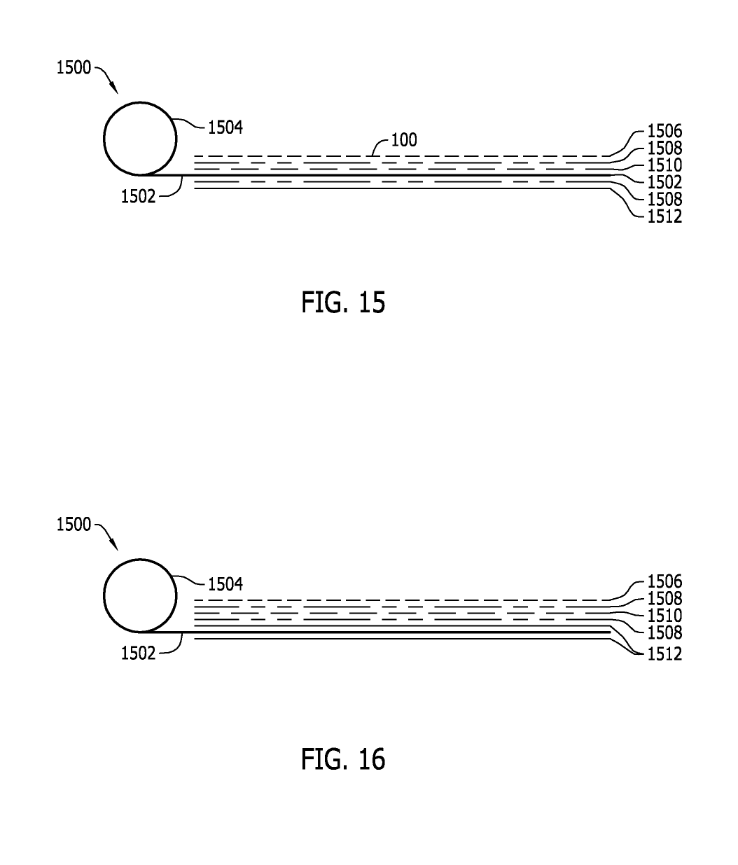

FIGS. 15-17 illustrate embodiments of a PV assembly including PV module 100 with a cooling system 1500 including a thermally conductive sheet 1502 integrated into module 100. In general, a thin sheet of material with relatively high thermal conductivity is embedded in PV module 100 during the lamination process for constructing PV module 100. The conductive sheet 1502 extends out of PV module 100 and is thermally coupled to a pipe 1504 through which a heat transfer fluid flows. Heat is transferred from PV module 100 to the heat transfer fluid via conductive sheet 1502. The heat transfer fluid is cooled and recirculated through system 1500. The heat carried by the heat transfer fluid may be used for other applications, such as heating water, heating air, etc.

FIGS. 15 and 16 are cross-sections of two embodiments of PV module 100 and system 1500. In this embodiment, the laminate of PV module 100 includes a glass surface 1506, two layers of encapsulant 1508 surrounding solar cell 1510 and conductive sheet 1502, and a back sheet 1512. In FIG. 16, the laminate of PV module 100 includes glass surface 1506, two layers of encapsulant 1508 surrounding solar cell 1510, and two back sheets 1512 surrounding conductive sheet 1502. In this embodiments, the encapsulant comprises ethylene vinyl acetate (EVA). In other embodiments any other suitable encapsulant may be used. In this embodiments, back sheets 1512 are a polyvinyl fluoride (PVF) material. In other embodiments, back sheets 1512 may be any other suitable back sheet material or a laminate of materials, including, for example a laminate of PVF surrounding a polyester material.

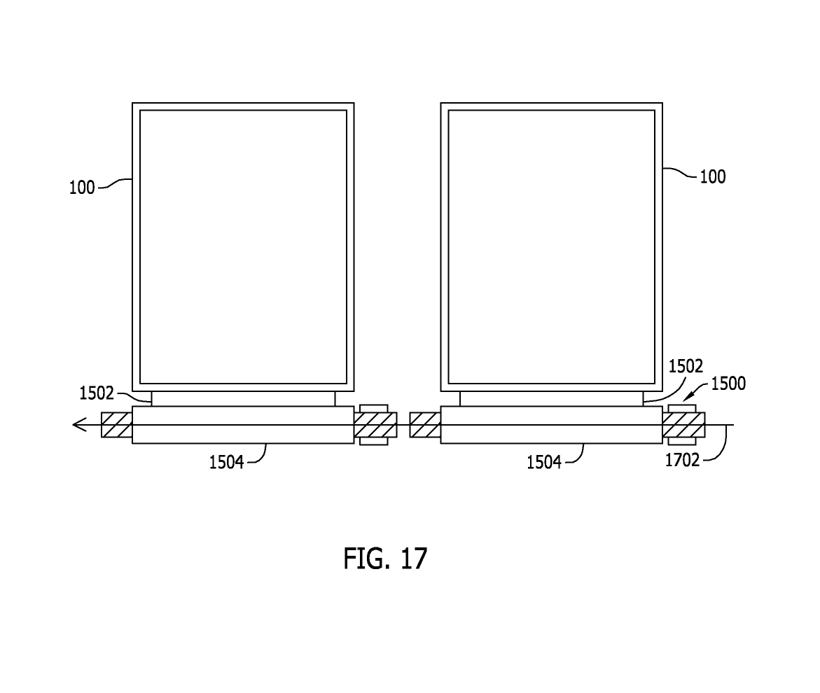

FIG. 17 is a top plan view of a portion of an array 1700 of PV modules 100 including cooling system 1500. A flow of heat transfer fluid through pipes 1504 is represented by a directional arrow 1702.

In this embodiment, pipes 1504 are metal pipes having a circular cross-section. In some embodiments, pipes 1504 are made of aluminum or of copper. In still other embodiments, pipes 1504 may comprise any suitable material allowing pipes 1504 to function as described herein, including non-metallic pipes, and pipes that are made of different metals and/or combinations of metals. In some embodiments, pipes 1504 have a square cross-section or any other suitably shaped cross-section.

Methods and systems including cooling systems as described herein achieve superior results compared to known methods and systems. For example, the cooling systems of this disclosure provide PV assemblies that may operate at lower temperatures than assemblies without such cooling systems or using other known systems. By reducing the temperature of the PV modules, the cooling systems may increase the efficiency of the PV modules. Moreover, some embodiments include recirculated heat transfer fluid that may be used for other purposes. For example, rather than simply discharging extracted heat to the environment around a PV module, some embodiments may use the heat collected from a PV module to heat air or water, or for any other suitable use.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. A photovoltaic (PV) assembly comprising:
a PV module including a solar panel comprising a top surface and a bottom surface;
a first rail and a second rail coupled to the PV module, the first rail and the second rail configured to support the PV module and extend below the bottom surface of the PV module; and
a cooling fluid assembly coupled against the bottom surface of the PV module, the cooling fluid assembly comprising:
a conduit assembly coupled to the bottom surface of the PV module, the conduit assembly comprising at least one conduit configured for containing a flow of heat transfer fluid through the at least one conduit; and
a connector assembly extending from at least one of the first rail and the second rail to the conduit assembly, the connector assembly configured to maintain the conduit assembly against the bottom surface of the PV module.

2. The PV assembly of claim 1, wherein the connector assembly comprises a first rigid support leg extending from the first rail to the conduit assembly, and a second rigid support leg extending from the second rail to the conduit assembly.

3. The PV assembly of claim 2, wherein the first rigid support leg is bolted to the first rail, and the second rigid support leg is bolted to the second rail.

4. The PV assembly of claim 1, wherein the connector assembly comprises a first spring compressed between the first rail and the conduit assembly, and a second spring compressed between the second rail and the conduit assembly, wherein the first and second springs provide a bias force resisting movement of the conduit assembly away from contact with the bottom surface of the PV module.

5. The PV assembly of claim 1, wherein the conduit assembly comprises a base coupled to the bottom surface of the PV module, and the at least one conduit comprises a plurality of thermally conductive pipes attached to the base, the thermally conductive pipes each configured for containing a flow of a heat transfer fluid.

6. The PV assembly of claim 5, wherein the conduit assembly further comprises a thermally conductive sheet connected to the thermally conductive pipes opposite the base.

7. The PV assembly of claim 5, wherein the thermally conductive pipes have a circular cross-sectional geometry.

8. The PV assembly of claim 5, wherein the thermally conductive pipes have a square cross-sectional geometry.

9. The PV assembly of claim 1, wherein the conduit assembly further comprises a heat transfer fluid contained within the at least one conduit.

10. The PV assembly of claim 1, wherein one side of the at least one conduit is defined by the bottom surface of the PV module.

11. A photovoltaic (PV) assembly comprising:
a PV module including a solar panel comprising a top surface and a bottom surface;
a header coupled to a first end of the PV module, the header module comprising at least one port configured to dispense a heat transfer fluid onto the top surface of said PV module; and
a collector assembly coupled to a second end of the PV module opposite the first end of the PV module, the collector assembly configured to collect heat transfer fluid from the top surface of the PV module, wherein the first end of the PV module is at a higher elevation than the second end of the PV module.

12. A photovoltaic (PV) assembly comprising:
a PV module comprising a plurality of laminated layers, the PV module having a top surface, a bottom surface, and a plurality of edges generally extending between the top surface and the bottom surface, wherein the plurality of layers comprise:
a solar cell including a top side and a bottom side;
a first encapsulant layer adjacent the top side of the solar cell;
a second encapsulant layer below the bottom side of the solar cell; and
a thermally conductive sheet below the bottom side of the solar cell, the thermally conductive sheet extending beyond one of the plurality of edges of the PV module.

13. The PV assembly of claim 12, wherein a first side of the thermally conductive sheet is positioned adjacent the bottom side of the solar cell and the second encapsulant layer is adjacent a second side of the thermally conductive sheet opposite the first side.

14. The PV assembly of claim 12, wherein the second encapsulant layer comprises a first side adjacent the bottom side of the solar cell and a second side opposite the first side.

15. The PV assembly of claim 14, wherein the plurality of layers further comprises a backing sheet having a first side adjacent the second side of the second encapsulant layer and wherein the thermally conductive sheet is adjacent a second side of the backing sheet opposite the first side.

16. The PV assembly of claim 12, further comprising a cooling assembly thermally coupled to the thermally conductive sheet.

17. The PV assembly of claim 16, wherein the cooling assembly comprises at least one pipe configured to retain a flow of heat transfer fluid.

18. The PV assembly of claim 17, wherein the at least one pipe is a thermally conductive pipe.

19. The PV assembly of claim 17, wherein the at least one pipe has a circular cross-sectional geometry.
